(19) United States
(12) Patent Application Publication
(10) Pub. No.: US 2015/0255675 A1
(43) Pub. Date: Sep. 10, 2015

(54) LIGHT-EMITTING DEVICE

(71) Applicant: LG INNOTEK CO., LTD., Seoul (KR)

(72) Inventors: Hyun don Song, Seoul (KR); Tae Lim Lee, Seoul (KR); Dong Ha Kim, Seoul (KR); Jin Wook Lee, Seoul (KR)

(73) Assignee: LG INNOTEK CO., LTD., Seoul (KR)

(21) Appl. No.: 14/419,156

(22) PCT Filed: Aug. 1, 2013
(86) PCT No.: PCT/KR2013/006928

§ 371 Date: Feb. 2, 2015

(30) Foreign Application Priority Data
Aug. 2, 2012 (KR) 10-2012-0084734

(51) Int. Cl. H01L 33/14; H01L 33/04; H01L 33/10; H01L 33/30; H01L 33/36

(52) U.S. Cl. CPC H01L 33/14; H01L 33/30; H01L 33/36; H01L 33/10; H01L 33/04

(57) ABSTRACT

A light-emitting device, according to one embodiment, comprises a light-emitting structure having a silicon substrate, a first conductive type semiconductor layer disposed on the silicon substrate, an active layer, and a second conductive type semiconductor layer, a conductive layer facing the active layer between the silicon substrate and the first conductive type semiconductor layer, a first electrode which is disposed on the first conductive type semiconductor layer, penetrates or bypasses the first conductive type semiconductor layer, and is electrically connected to the conductive layer, and a second electrode disposed on the second conductive type semiconductor layer.

### TECHNICAL FIELD

Embodiments relate to a light emitting device.

### BACKGROUND ART

A group III-V compound semiconductor, such as GaN, has been widely used in the field of optoelectronics since the semiconductor has wide and easily adjustable band gap energy and other advantages.

FIG. 1 is a view showing a general horizontal-type light emitting device. Thicker arrows indicate flow of a larger number of electrons.

The horizontal-type light emitting device shown in FIG. 1 includes a substrate 10 and a light emitting structure 20. The light emitting structure 20 includes an n-type semiconductor layer 22 disposed on the substrate 10, an active layer 24 disposed between the n-type semiconductor layer 22 and a p-type semiconductor layer 26, the p-type semiconductor layer 26 disposed on the active layer 24, and first and second electrodes 30 and 32 electrically contacting the n-type and p-type semiconductor layers 22 and 26, respectively.

A larger portion of electrons supplied through the n-type first electrode 30 tend to flow through the shortest course 40 from the first electrode 30 to the active layer 24. That is, in the light emitting device shown in FIG. 1, a larger number of electrons flow through a side 40 close to the first electrode 30, whereas a smaller number of electrons flow through a side 44 far from the first electrode 30.

Such non-uniformity in flow of the electrons may reduce internal quantum efficiency (IQE) and cause local heating of the light emitting device, thereby lowering reliability of the light emitting device.

### DISCLOSURE

### Technical Problem

Embodiments provide a light emitting device with improved current spreading.

### Technical Solution

In one embodiment, a light emitting device includes a silicon substrate, a light emitting structure disposed on the silicon substrate, the light emitting structure including a first conductive semiconductor layer, an active layer, and a second conductive semiconductor layer, a conductive layer disposed between the silicon substrate and the first conductive semiconductor layer, the conductive layer being opposite to the active layer, a first electrode disposed on the first conductive semiconductor layer, the first electrode being electrically connected to the conductive layer while penetrating the first conductive semiconductor layer or while bypassing the first conductive semiconductor layer, and a second electrode disposed on to the second conductive semiconductor layer.

The silicon substrate may have a (111) crystal plane as a principal plane.

The conductive layer may include a first area opposite to the active layer and a second area extending from the first area, the second area being connected to the first electrode.

The conductive layer and the first electrode may be formed of the same material.

For example, a penetration part of the first electrode penetrating the first conductive semiconductor layer may have a width of 0.5 μm to 1.5 μm.

Alternatively, the first electrode may include a first segment disposed on the first conductive upper semiconductor layer in a first direction and a second segment extending from the first segment in a second direction different from the first direction, the second segment electrically contacting the conductive layer.

The light emitting device may further include another first conductive semiconductor layer, different from the first conductive semiconductor layer, disposed between the conductive layer and the silicon substrate.

For example, the conductive layer may be formed in a plate shape, a separated line shape, or a grid shape.

In addition, the conductive layer may have a light extraction pattern for reflecting light from the active layer. The light extraction pattern may be formed in a periodic or non-periodic shape, may have a convex-concave structure, may be formed in a hemispherical shape, a truncated shape, or a secondary prism shape, or may be formed in an irregular saw-toothed shape or a rectangular shape.

For example, the conductive layer may have a thickness of 100 nm to 500 nm.

The conductive layer may include a material exhibiting a reflection property.

For example, the conductive layer may be formed of a material or an alloy of materials selected from a group consisting of titanium (Ti), nickel (Ni), gold (Au), platinum (Pt), tantalum (Ta), molybdenum (Mo), silicon (Si), tungsten (W), copper (Cu), aluminum (Al), silver (Ag), and rhodium (Rh). In addition, the conductive layer may selectively include gold (Au), a copper alloy (Cu alloy), nickel (Ni), copper-tungsten (Cu—W), or a carrier wafer.

A surface of the conductive layer opposite to the active layer may be flat.

The conductive layer may be a single body. Alternatively, the conductive layer may be divided into a plurality of sub bodies spaced apart from each other.

The light emitting device may further include an air layer disposed between the sub bodies of the conductive layer and the first conductive semiconductor layer.

### Advantageous Effects

In a light emitting device according to embodiments, a conductive layer disposed between a light emitting layer and a substrate is electrically connected to a first electrode. As a result, the flow of carriers from the first electrode to an active layer is uniform. Consequently, it is possible to reduce driving voltage, to improve internal quantum efficiency, and to fundamentally prevent local heating of the light emitting device, thereby improving reliability of the light emitting device. In addition, the conductive layer is disposed in the middle of a first conductive semiconductor, i.e. between a first conductive lower semiconductor layer and a first conductive upper semiconductor layer. Consequently, it is possible to improve dislocation density.

### DESCRIPTION OF DRAWINGS

FIG. 1 is a view showing a general horizontal-type light emitting device.

FIG. 2 is a sectional view showing a light emitting device according to an embodiment.

FIG. 3 is a sectional view showing a light emitting device according to another embodiment.

FIG. 4 is a sectional view showing a light emitting device according to another embodiment.

FIG. 5 is a sectional view showing a light emitting device according to a further embodiment.

FIGS. 6a to 6c are plan views of the light emitting devices according to the embodiments.

FIGS. 7a to 7f are sectional views illustrating a method of manufacturing the light emitting device shown in FIG. 2 according to an embodiment.

FIGS. 8a to 8g are sectional views illustrating a method of manufacturing the light emitting device shown in FIG. 3 according to an embodiment.

FIGS. 9a to 9d are sectional views illustrating a method of manufacturing the light emitting device shown in FIG. 4 according to an embodiment.

FIGS. 10a to 10f are sectional views illustrating a method of manufacturing the light emitting device shown in FIG. 5 according to an embodiment.

FIG. 11 is a sectional view showing a light emitting device package according to an embodiment.

FIG. 12 is a perspective view showing a lighting unit according to an embodiment.

FIG. 13 is an exploded perspective view showing a backlight unit according to an embodiment.

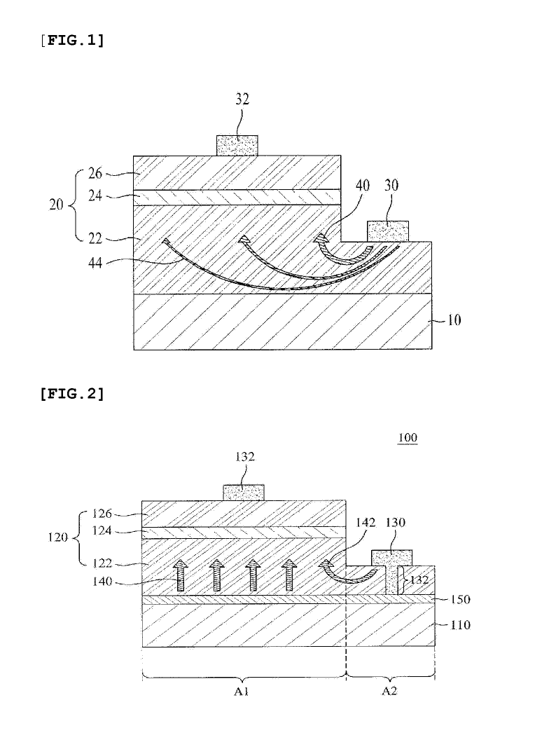

### BEST MODE

Reference will now be made in detail to embodiments, examples of which are illustrated in the accompanying drawings. However, the present disclosure may be embodied in many different forms and should not be construed as limited to the embodiments set forth herein. Rather, these embodiments are provided so that this disclosure will be thorough and complete, and will fully convey the disclosure to those skilled in the art.

In the following description of the embodiments, it will be understood that, when each element is referred to as being on or “under” another element, it can be “directly” on or under another element or can be “indirectly” formed such that an intervening element is also present. In addition, terms such as “on” or “under” should be understood on the basis of the drawings.

In the drawings, the thickness or size of each layer is exaggerated, omitted, or schematically illustrated for convenience of description and clarity. In addition, the size or area of each constituent element does not entirely reflect the actual size thereof.

FIG. 2 is a sectional view showing a light emitting device 100 according to an embodiment.

The light emitting device 100 shown in FIG. 2 includes a substrate 110, a light emitting structure 120, first and second electrodes 130 and 132, and a conductive layer 150.

The substrate. 110 may include, at least one selected from among sapphire (Al₂0₃), GaN, SiC, ZnO, GaP, InP, Ga₂0₃, and GaAs. Alternatively, the substrate 110 may be a silicon substrate having a (111) crystal plane as a principal plane.

The conductive layer 150 is disposed on the substrate 110. The conductive layer 150 may be divided into a first area A1 and a second area A2. The first area A1 is an area opposite to an active layer 124, and the second area A2 is an area extending from the first area A1 and electrically contacting the first electrode 130.

The conductive layer 150 may contact the first electrode 130 to provide electrons (or holes) to the light emitting structure 120. To this end, the conductive layer 150 may be formed of a metal exhibiting high electric conductivity. Alternatively, the conductive layer 150 may include a material exhibiting electric conductivity in addition to the metal.

In addition, the conductive layer 150 may reflect light emitted from the light emitting structure 120. To this end, the conductive layer 150 may include a material exhibiting a reflection property as well as electric conductivity.

For example, the conductive layer 150 may be formed of a material or an alloy of materials selected from a group consisting of titanium (Ti), platinum (Pt), tantalum (Ta), molybdenum (Mo), silicon (Si), tungsten (W), copper (Cu), aluminum (Al), silver (Ag), and rhodium (Rh). In addition, the conductive layer 150 may selectively include gold (Au), copper alloy (Cu alloy), nickel (Ni), copper-tungsten (Cu—W), and a carrier wafer (e.g. GaN, Si, Ge, GaAs, ZnO, SiGe, SIC, SiGe, and Ga₂O₃).

The conductive layer 150 may have a thickness of 100 nm or more although the thickness of the conductive layer 150 is not particularly restricted.

For example, the conductive layer 150 may have a thickness of 100 nm to 500 nm.

The light emitting structure 120 is disposed on the substrate 110. The light emitting structure 120 may include a first conductive semiconductor layer 122, an active layer 124, and a second conductive semiconductor layer 126, which are sequentially stacked on the substrate 110.

The first conductive semiconductor layer 122 is disposed at the top of the conductive layer 150.

The first conductive semiconductor layer 122 may be embodied by a group III-V or II-VI compound semiconductor doped with a first conductive dopant. In a case in which the first conductive semiconductor layer 122 is an n-type semiconductor layer, the first conductive dopant may include Si, Ge, Sn, Se, or Te as an n-type dopant. However, the disclosure is not limited thereto.

The first conductive semiconductor layer 122 may include, for example, a semiconductor material having a formula of AlₓIn_{y}Ga_{(1-x-y)}N (0≦x≦1, 0≦y≦1, 0≦x+y≦1). The first conductive semiconductor layer 122 may be formed of one or more selected from among GaN, InN, AlN, InGaN, AlGaN, InAlGaN, AlInN, AlGaAs, InGaAs, AlInGaAs, GaP, AlGaP, InGaP, AlInGaP, and InP.

The active layer 124 is a layer in which electrons (or holes) injected through the first conductive semiconductor layer 122 and holes (or electrons) injected through the second conductive semiconductor layer 126 are coupled to emit light having energy decided by an inherent energy band of a material constituting the active layer 124.

The active layer 124 may be formed to have at least one of a single well structure, a double hetero structure, a multi well structure, a single quantum well structure, a multi quantum well (MQW) structure, a quantum-wire structure, or a quantum dot structure.

A well layer/barrier layer of the active layer 124 may include one or more pair structures selected from among InGaN/GaN, InGaN/InGaN, GaN/AlGaN, InAlGaN/GaN, GaAs(InGaAs)/AlGaAs, and GaP(InGaP)/AlGaP. However, the disclosure is not limited thereto. The well layer may include a material having a narrower band gap than the barrier layer.

A conductive clad layer (not shown) may be disposed on and/or under the active layer 124. The conductive clad layer may be formed of a semiconductor having a wider band gap than the barrier layer of the active layer 124. For example, the conductive clad layer may include GaN, AlGaN, InAlGaN, or a super lattice structure. In addition, the conductive clad layer may be doped as an n-type or p-type semiconductor.

The second conductive semiconductor layer 126 may be embodied by a group III-V or II-VI compound semiconductor. The second conductive semiconductor layer 126 may be doped with a second conductive dopant. The second conductive semiconductor layer 126 may include, for example, semiconductor material having a formula of InₓAl_{y}Ga_{1-x-y}N (0≦x≦1, 0≦y≦1, 0≦x+y≦1). In a case in which the second conductive semiconductor layer 126 is a p-type semiconductor layer, the second conductive dopant may include Mg, Zn, Ca, Sr, or Ba, etc. as a p-type dopant.

The first conductive semiconductor layer 122 may be embodied by a p-type semiconductor layer, and the second conductive semiconductor layer 126 may be embodied by an n-type semiconductor layer. Alternatively, the first conductive semiconductor layer 122 may be embodied by an n-type semiconductor layer, and the second conductive semiconductor layer 126 may be embodied by a p-type semiconductor layer.

The light emitting structure 120 may be formed to have any one selected from among an N-P junction structure, a P-N junction structure, an N-P-N junction structure, and a P-N-P junction structure.

In embodiments which will hereinafter be described, the first conductive semiconductor layer 122 will be described as an n-type semiconductor layer, and the second conductive semiconductor layer 126 will be described as a p-type semiconductor layer for the sake of convenience. However, the disclosure is not limited thereto.

The first electrode 130 is electrically connected to the first conductive semiconductor layer 122. For example, as shown in FIG. 2, the first electrode 130 may electrically contact the conductive layer 150 while penetrating the first conductive semiconductor layer 122. However, the disclosure is not limited thereto. The first electrode 130 may electrically contact the conductive layer 150 in various manners. The second electrode 132 electrically contacts the second conductive semiconductor layer 126.

The first and second electrodes 130 and 132 may each be formed of a metal. In addition, the first and second electrodes 130 and 132 may each be formed of a reflective electrode material exhibiting an ohmic property. For example, the first and second electrodes 130 and 132 may each be formed to have a single or multi layer structure including at least one selected from among aluminum (Al), titanium chrome (Cr), nickel (Ni), copper (Cu), and gold (Au).

A penetration part 132 of the first electrode 130 penetrating the first conductive semiconductor layer 122 may have a width of 0.5 μm to 1.5 μm although the width of the penetration part 132 is not particularly restricted. For example, the penetration part 132 may have a width of 1.0 μm.

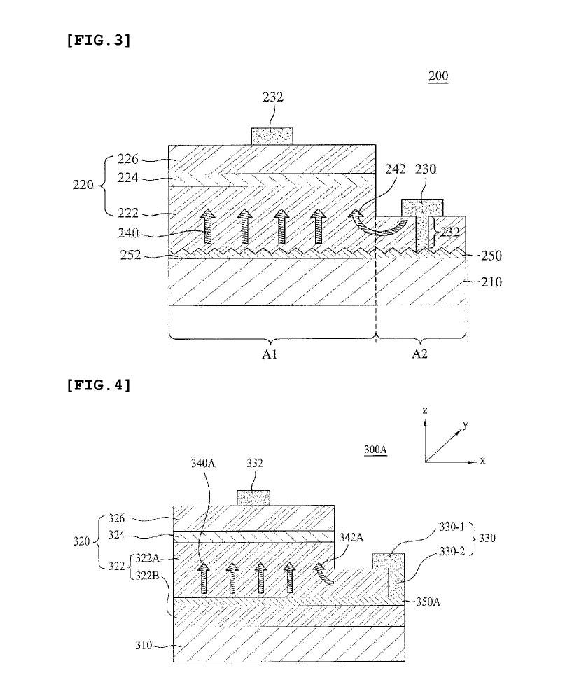

FIG. 3 is a sectional view showing a light emitting device 200 according to another embodiment.

The light emitting device 200 shown in FIG. 3 is identical to the light emitting device 100 shown in FIG. 2 except that the conductive layer 150 of the light emitting device 100 shown in FIG. 2 is flat, whereas a conductive layer 250 of the light emitting device 200 shown in FIG. 3 has a light extraction pattern 252. That is, a substrate 210, first and second conductive semiconductor layers 222 and 226, an active layer 224, first and second electrodes 230 and 232, and a penetration part 232 shown in FIG. 3 correspond to and perform the same functions as the substrate 110, the first and second conductive semiconductor layers 122 and 126, the active layer 124, the first and second electrodes 130 and 132, and the penetration part 132 shown in FIG. 2, respectively, and thus a detailed description thereof will be omitted.

Generally, in a case in which the substrate 110 is a silicon substrate, visible light emitted from the active layer 124 may be absorbed by the silicone substrate to lowering of light emission efficiency. In order to prevent this, the conductive layer 250 of the light emitting device 200 exemplarily shown in FIG. 3 has the light extraction pattern 252, which reflects light from the active layer 224, thereby improving light emission efficiency.

In order to reflect light from the active layer 224, the light extraction pattern 252 of the conductive layer 250 shown in FIG. 3 may be formed in a periodic or non-periodic shape. The light extraction pattern 252 may have a convex concave structure. In addition, the light extraction pattern 252 may have various shapes, such as a hemispherical shape, a truncated shape, and a secondary prism shape. In FIG. 3, the light extraction pattern 252 is irregularly formed in a saw-toothed shape. Alternatively, the light extraction pattern 252 may be formed in a rectangular shape.

FIG. 4 is a sectional view showing a light emitting device 300A according to another embodiment.

The light emitting device 300A shown in FIG. 4 is identical to the light emitting device 100 shown in FIG. 2 except an arrangement structure of a conductive layer 350A of the light emitting device 300A shown in FIG. 4 and an electrical connection form between a first electrode 330 and the conductive layer 350A. That is, a substrate 310, first and second conductive semiconductor layers 322 and 326, an active layer 324, and first and second electrodes 330 and 332 shown in FIG. 4 correspond to and perform the same functions as the substrate 110, the first and second conductive semiconductor layers 122 and 126, the active layer 124, and the first and second electrodes 130 and 132 shown in FIG. 2, respectively, and thus a detailed description thereof will be omitted. The light emitting device 300A shown in FIG. 4 is different from the light emitting device 100 shown in FIG. 2 as follows.

The conductive layer 150 shown in FIG. 2 is disposed between the first conductive semiconductor layer 122 and the substrate 110, whereas the conductive layer 350A shown in FIG. 4 is disposed between a first conductive upper semiconductor layer 322A and a first conductive lower semiconductor layer 322B. That is, the conductive layer 350A is disposed in the middle of the first conductive semiconductor layer 322. For example, in the light emitting device 300A shown in FIG. 4, the first conductive lower semiconductor layer 322B is further disposed between the conductive layer 350A and the substrate 310 unlike FIG. 2. The conductive layer 350A may have a thickness of 100 nm or more although the thickness of the conductive layer 350A is not particularly restricted. For example, the conductive layer 350A may have a thickness of 100 nm to 500 nm.

The first conductive semiconductor layer 322 includes the first conductive upper semiconductor layer 322A and the first conductive lower semiconductor layer 322B. The first conductive upper semiconductor layer 322A and the first conductive lower semiconductor layer 322B each correspond to and perform the same function as the first conductive semiconductor layer 122 shown in FIG. 2, and thus a detailed description thereof will be omitted.

In addition, the first electrode 130 shown in FIG. 2 electrically contacts the conductive layer 150 while penetrating the first conductive semiconductor layer 122, whereas the first electrode 330 shown in FIG. 4 is electrically connected to the conductive layer 350A while bypassing the first conductive upper semiconductor layer 322A.

The first electrode 330 includes a first segment 330-1 and a second segment 330-2. The first segment 330-1 is disposed on the first conductive upper semiconductor layer 322A in a first direction x. The second segment 330-2 extends from the first segment 330-1 in a second direction, such as a z direction, different from the first direction x to electrically contact the conductive layer 350A.

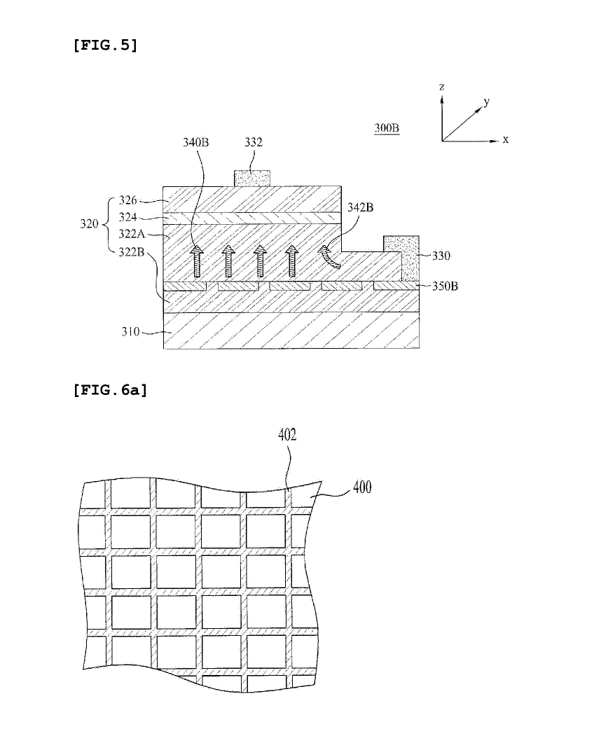

FIG. 5 is a sectional view showing a light emitting device 300B according to a still another embodiment.

The light emitting device 300B shown in FIG. 5 is identical to the light emitting device 300A shown in FIG. 4 except that the conductive layer 350A of the light emitting device 300A shown in FIG. 4 is a single body, whereas conductive layer 350B of the light emitting device 300B shown in FIG. 5 is divided into a plurality of sub bodies, which may be spaced apart from each other. Therefore, the same reference numerals are used and a detailed description thereof will be omitted.

Meanwhile, the light emitting device 300B shown in FIG. 5 may correspond to a side sectional view of the light emitting device 300A shown in FIG. 4 when viewed in an x-axis direction.

In the light emitting device 300A or 300B shown in FIG. 4 or 5, an initial buffer layer (not shown) and an undoped GaN layer (not shown) may be further disposed between the substrate 310 and the first conductive lower semiconductor layer 322B.

The substrate 310 may include a conductive material or a non-conductive material. The initial buffer layer functions to prevent the occurrence of a problem caused due to lattice mismatching between the substrate 310 and nitride light emitting structure 320. To this end, the initial buffer layer may include at least one material selected from a group consisting of Al, In, N, and Ga. In addition, the initial buffer layer may have a single or multi layer structure.

Meanwhile, the conductive layers 150, 250, 350A, and 350B according to the above-described embodiments may have various planar shapes.

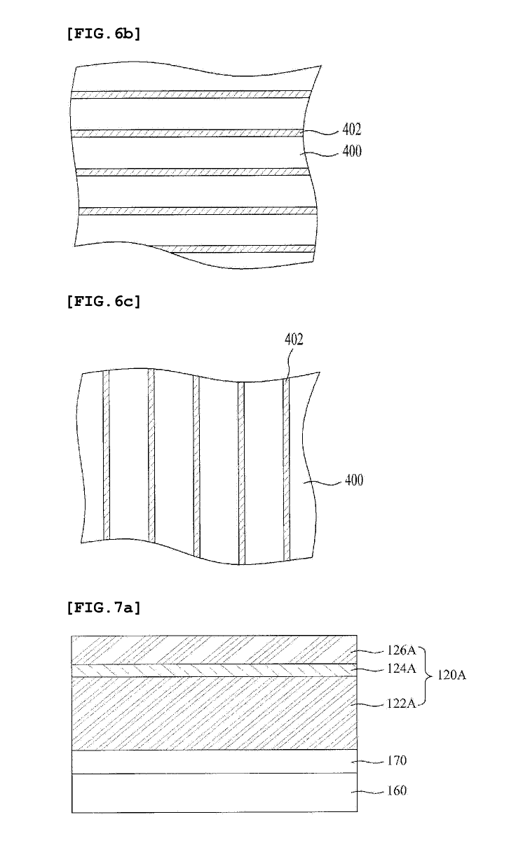

FIGS. 6a to 6c are plan views of the light emitting devices 100, 200, 300A, and 300B according to the embodiments. Reference numeral 400 indicates the substrate 110 or the first conductive lower semiconductor layer 322B, and reference numeral 402 indicates the conductive layer 150, 250, 350A, or 350B shown in each of FIGS. 2 to 5.

FIGS. 6a to 6c are shown as schematic plan views of the conductive layers 150, 250, 350A, and 350B for easy understanding of the embodiments.

For example, FIGS. 6a to 6c may be plan views of the conductive layers 150 and 250 when the light emitting structures 120 and 220, the first electrodes 130 and 230, and the second electrodes 132 and 232 are omitted from the light emitting devices 100 and 200 shown in FIGS. 2 and 3. In this case, reference numeral 400 indicates the substrate 110 or 210.

Alternatively, FIGS. 6a to 6c may be plan views of the conductive layers 350A and 350B when the second conductive semiconductor layers 326, the active layers 324, the first conductive upper semiconductor layers 322A, the first electrodes 330, and the second electrodes 332 are omitted from the light emitting devices 300A and 300B shown in FIGS. 4 and 5. In this case, reference numeral 400 indicates the first conductive lower semiconductor layer 322B.

According to embodiments, the conductive layer 402 may cover the entirety of the first conductive lower semiconductor layer 322B (or the substrate 110 or 210) in a plate shape. Alternatively, the conductive layer 402 may be formed in a grid shape as shown in FIG. 6a or in a separated line shape as shown in FIG. 6b or 6c.

In the light emitting device 100, 200, 300A, or 300B shown in each of FIGS. 2 to 5, electrons supplied through the first electrode 130, 230, or 330 widely flow to the active layer 124, 224, or 324 in a spreading state from the conductive layer 150, 250, 350A, or 350B via the first conductive semiconductor layer 122 or 222 (or the first conductive upper semiconductor layer 322A). As a result, a tendency for the electrons to flow close to the first electrode 130, 230, or 330 is alleviated, thereby achieving uniform flow of the current. That is, current spreading is improved. In FIGS. 2 to 5, thicker arrows indicate flow of a larger number of electrons. It can be seen that the thicknesses of the arrows are uniform (140, 142, 240, 242, 340A, 342A, 340B, and 342B) irrespective of the distance from the first electrode 130, 230, or 330.

As the current flow is uniform as described above, it is possible to reduce driving voltage, to improve internal quantum efficiency (IQE) of the light emitting device 100, 200, 300A, or 300B, and to solve a reliability lowering problem due to local heating of the light emitting device 100, 200, 300A, or 300B.

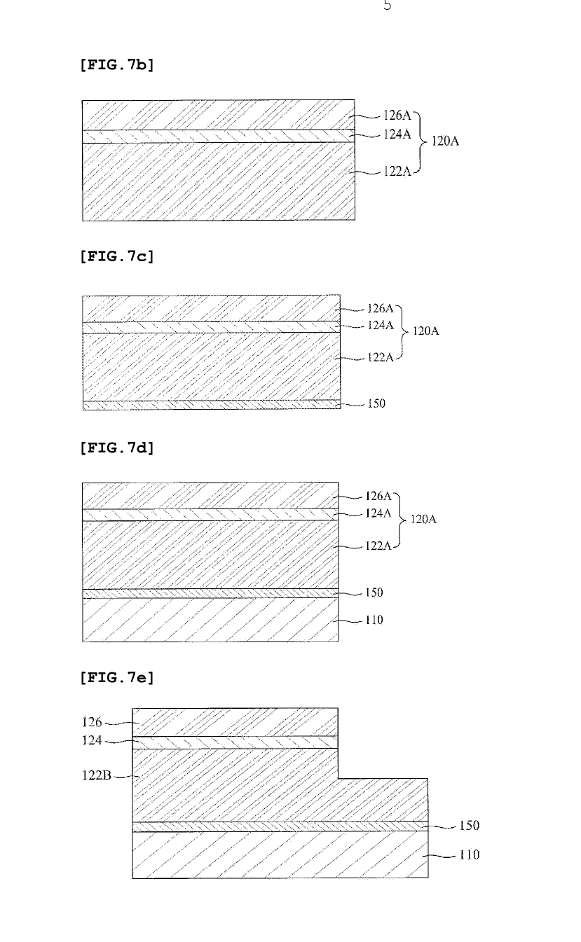

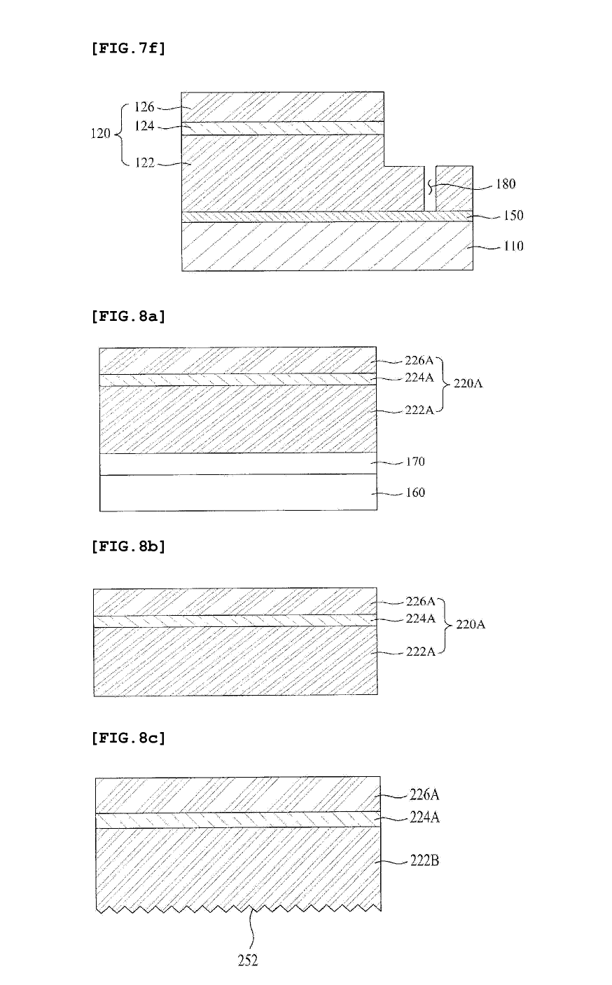

Hereinafter, a method of manufacturing the light emitting device 100 shown in FIG. 2 according to an embodiment will be described with reference to FIGS. 7a to 7f. However, the disclosure not limited thereto. The light emitting device 100 shown in FIG. 2 may be manufactured using other different methods.

FIGS. 7a to 7f are sectional views illustrating a method of manufacturing the light emitting device 100 shown in FIG. 2 according to an embodiment.

Referring to FIG. 7a, an initial buffer layer 170 is formed on a support substrate 160, The support substrate 160 may include a conductive material or a non-conductive material. In a case in which the support substrate 160 is a silicon substrate, the support substrate 160 may have a large diameter and high thermal conductivity. However, a nitride light emitting structure layer 120A may crack due to a difference in a coefficient of thermal expansion and lattice mismatching between the silicon and a nitride light emitting structure layer 120A. In order to prevent this, the buffer layer 170 may be formed on the support substrate 160. The buffer layer 170 may include at least one material selected from a group consisting of Al, In, N, and Ga. In addition, the buffer layer 170 may have a single or multi layer structure.

After the buffer layer 170 is formed on the support substrate 160, as shown in FIG. 7a, a first conductive semiconductor layer 122A, an active layer 124A, and a second conductive semiconductor layer 126A may be sequentially stacked on the buffer layer 170 to form a light emitting structure layer 120A.

The first conductive semiconductor layer 122A may be embodied by a group III-V or II-VI compound semiconductor doped with a first conductive dopant. In a case in which the first conductive semiconductor layer 122A is an n-type semiconductor layer, the first conductive dopant may include Si, Ge, Sn, Se, or Te as an n-type dopant. However, the disclosure is not limited thereto.

The first conductive semiconductor layer 122A may include, for example, a semiconductor material having a formula of AlₓIn_{y}Ga_{(1-x-y)}N (0≦x≦1, 0≦y≦1, 0≦x+y≦1). The first conductive semiconductor layer 122A may be formed of one or more selected from among GaN, InN, AlN, InGaN, AlGaN, InAlGaN, AlInN, AlGaAs, InGaAs, AlInGaAs, GaP, AlGaP, InGaP, AlInGaP, and InP.

The active layer 124A may be formed to have at least one of a single well structure, a multi well structure, a single quantum well structure, a multi quantum well structure, a quantum-wire structure, or a quantum dot structure. For example, trimethyl gallium (TMGa), ammonia (NH₃), nitrogen (N₂), and trimethyl indium (TMIn) may be injected into the active layer 124A such that the active layer 124A has a multi quantum well structure. However, the disclosure is not limited thereto.

A well layer/barrier layer of the active layer 124A may be formed to have one or more pair structures selected from among InGaN/GaN, InGaN/InGaN, GaN/AlGaN, InAlGaN/GaN, GaAs(InGaAs)/AlGaAs, and GaP(InGaP)/AlGaP. However, the disclosure is not limited thereto. The well layer may be formed of a material having a narrower band gap than the barrier layer.

A conductive clad layer (not shown) may be further formed on and/or under the active layer 124A. The conductive clad layer may be formed of a semiconductor having a wider band gap than the barrier layer of the active layer 124. For example, the conductive clad layer may be formed to have GaN, AlGaN, InAlGaN, or a super lattice structure, etc. In addition, the conductive clad layer may be doped as an n-type or p-type semiconductor.

The second conductive semiconductor layer 126A may be formed using a group III-V or II-VI compound semiconductor. The second conductive semiconductor layer 126A may be doped with a second conductive dopant. The second conductive semiconductor layer 126A may be formed using, for example, semiconductor material having a formula of InₓAl_{y}Ga_{1-x-y}N (0≦x≦1, 0≦y≦1, 0≦x+y≦1). In a case in which the second conductive semiconductor layer 126A is a p-type semiconductor layer, the second conductive dopant may include Mg, Zn, Ca, Sr, or Ba, etc. as a p-type dopant.

Subsequently, as exemplarily shown in FIG. 7b, the support substrate 160 and the buffer layer 170 are removed. In a case in which the support substrate 160 is a silicon substrate, the silicon support substrate 160 is removed by wet etching. In addition, in a case in which the buffer layer 170 is formed of AlN, the buffer layer 170 is removed by dry etching.

Subsequently, as shown in FIG. 7c, a conductive layer 150 is formed at the top of the first conductive semiconductor layer 122A.

The conductive layer 150 may be formed using a material exhibiting a reflection property as well as electric conductivity. For example, the conductive layer 150 may be formed using a material or an alloy of materials selected from a group consisting of titanium (Ti), platinum (Pt), tantalum (Ta), molybdenum (MO), silicon (Si), tungsten (W), copper (Cu), aluminum (Al), silver (Ag), and rhodium (Rh), or a material selectively including gold (Au), a copper alloy (Cu alloy), nickel (Ni), copper-tungsten (Cu—W), a carrier wafer (e.g. GaN, Si, Ge, GaAs, ZnO, SiGe, SiC, SiGe, and Ga₂O₃, etc.).

Subsequently, as exemplarily shown in FIG. 7d, a substrate 110 is formed at the top of the conductive layer 150. The substrate 110 may be an insulative substrate. The substrate 110 may be formed using, for example, at least one selected from among sapphire (Al₂0₃), GaN, SiC, ZnO, GaP, InP, Ga₂0₃, and GaAs.

Subsequently, as exemplarily shown in FIG. 7e, the first conductive semiconductor layer 122A, the active layer 124A, and the second conductive semiconductor layer 126A are mesa-etched to expose a first conductive semiconductor layer 122E.

Subsequently, as exemplarily shown in FIG. 7f, a through hole 180 is formed in the first conductive semiconductor layer 122 exposed by mesa etching. The through hole 180 may be formed by an ordinary photolithography process. However, the disclosure is not limited thereto. The through hole 180 may be formed to have a diameter of 0.5 μm to 1.5 μm. For example, the through hole 180 may have a diameter of 1 μm.

Subsequently, the through hole 180 is filled with a metal to form a first electrode 130. At the same time, a second electrode 132 is formed at the top of the second conductive semiconductor layer 126. In addition, the first and second electrodes 130 and 132 may each be formed using a reflective electrode material exhibiting an ohmic property. For example, the first and second electrodes 130 and 132 may each be formed to have a single or multi layer structure including at least one selected from among aluminum (Al), titanium (Ti), chrome (Cr), nickel (Ni), copper (Cu), and gold (Au).

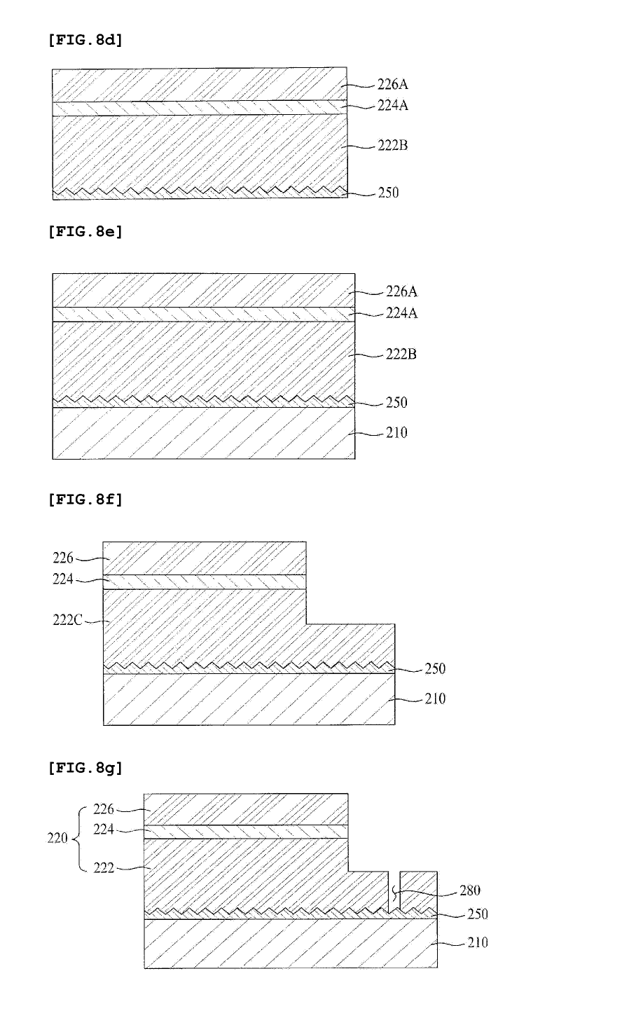

Hereinafter, a method of manufacturing the light emitting device 200 exemplarily shown in FIG. 3 according to an embodiment will be described with reference to FIGS. 8a to 8g. However, the disclosure is not limited thereto. The light emitting device 200 shown in FIG. 3 may be manufactured using other different-methods.

FIGS. 8a to 8g are sectional views illustrating a Method of manufacturing the light emitting device 200 shown in FIG. 3 according to an embodiment.

In a process sectional view shown in FIG. 8a, support substrate 160 and a buffer layer 170 correspond to the support substrate 160 and the buffer layer 170 shown in FIG. 7a, respectively. Therefore, the same reference numerals are used and a detailed description thereof will be omitted. In addition, in process sectional views shown in FIGS. 8a and 8b, a light emitting structure layer 220A including a first conductive semiconductor layer 222A, an active layer 224A, and a second conductive semiconductor layer 226A corresponds to the light emitting structure layer 120A including the first conductive semiconductor layer 122A, the active layer 124A, and the second conductive semiconductor layer 126A shown in FIGS. 7a and 7b. That is, FIGS. 8a and 8b are identical to FIGS. 7a and 7b, respectively, and thus a detailed description thereof will be omitted.

Subsequently, as shown in FIG. 8c, the top of an exposed first conductive semiconductor layer 222A is patterned to form a light extraction pattern 252. The light extraction pattern 252 formed at a first conductive semiconductor layer 2223 may be formed in a periodic or non-periodic shape. The light extraction pattern 252 may, have a convex-concave structure. In addition, the light extraction pattern 252 may have various shapes, such as a hemispherical shape, a truncated shape, and a secondary prism shape. Furthermore, the light extraction pattern 252 may be formed in a rectangular shape although the light extraction pattern 252 is formed in a saw-toothed shape as shown in FIG. 8c.

Subsequently, as shown in FIG. 8d, a conductive layer 250 is formed on the first conductive semiconductor layer 222B.

In process sectional views shown in FIGS. 8d to 8g, the conductive layer 250, a substrate 210, and a through hole 280 correspond to the conductive layer 150, the substrate 110, and the through hole 180 shown in FIGS. 7c to 7f, respectively. That is, FIGS. 8d to 8g are identical to FIGS. 7c to 7f, respectively, and thus a detailed description thereof will be omitted.

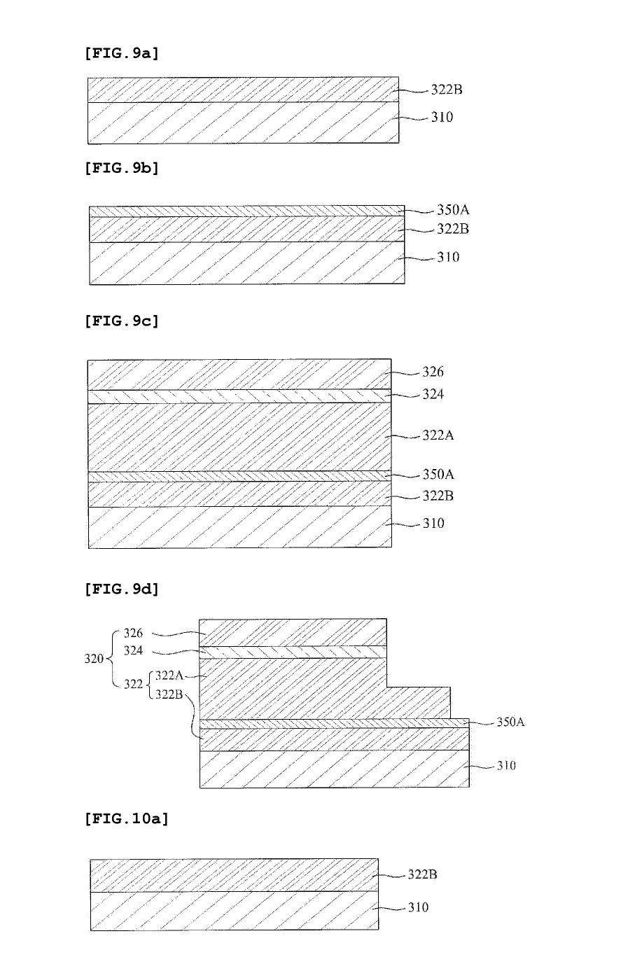

Hereinafter, a method of manufacturing the light emitting device 300A shown in FIG. 4 according to an embodiment will be described with reference to FIGS. 9a to 8d. However, the disclosure is not limited thereto. The light emitting device 300A shown in FIG. 4 may be manufactured using other different methods.

FIGS. 9a to 9d are sectional views illustrating a method of manufacturing the light emitting device 300A shown in FIG. 4 according to an embodiment.

Referring to FIG. 9a, a first conductive lower semiconductor layer 322B is formed on a substrate 310. The substrate 310 may be a conductive substrate or an insulative substrate. The substrate 310 may be formed using, example, at least one selected from among sapphire (Al₂0₃), GaN, SIC, ZnO, GaP, InP, Ga₂0₃, GaAs, and Si. The first conductive lower semiconductor layer 322B may be embodied by a group III-V or II-VI compound semiconductor doped with a first conductive dopant. In a case in which the first conductive lower semiconductor layer 322B is an n-type semiconductor layer, the first conductive dopant may include Si, Ge, Sn, Se, Te as an n-type dopant. However, the disclosure is not limited thereto.

The first conductive lower semiconductor layer 322B may be formed using, for example, a semiconductor material having a formula of AlₓIn_{y}Ga_{(1-x-y)}N (0≦x≦1, 0≦y≦1, 0≦x+y≦1). The first conductive lower semiconductor layer 322B may be formed of one or more selected from among GaN, InN, AlN, InGaN, AlGaN, InAlGaN, AlInN, AlGaAs, InGaAs, AlInGaAs, GaP, AlGaP, InGaP, AlInGaP, InP.

At this time, although not shown, an initial buffer layer (not shown) may be formed on the substrate 310, an undoped GaN (hereinafter, uGaN) layer (not shown) may be formed at the top of the initial buffer layer, and the first conductive lower semiconductor layer 322B may be formed at the top of the uGaN layer.

For example, the initial buffer layer may include at least one material selected from a group consisting of Al, In, N, and Ga. In addition, the initial buffer layer may have a single or multi layer structure.

Subsequently, as exemplarily shown in FIG. 9b, a conductive layer 350B is formed at the top of the first conductive lower semiconductor layer 322B. The conductive layer 350B may be formed using a material exhibiting a reflection property as well as electric conductivity. For example, the conductive layer 350A may be formed using a material or an alloy of materials selected from a group consisting of titanium (Ti), platinum (Pt), tantalum (Ta), molybdenum (Mo), silicon (Si), tungsten (W), copper (Cu), aluminum (Al), silver (Ag), and rhodium (Rh), or a material selectively including gold (Au), a copper alloy (Cu alloy), nickel (Ni), copper-tungsten (Cu—W), and a carrier wafer (e.g. GaN, Si, Ge, GaAs, ZnO, SiGe, SIC, SiGe, and Ga₂O₃).

Subsequently, as shown in FIG. 9c, a first conductive upper semiconductor layer 322A, an active layer 324, and a second conductive semiconductor layer 326 are sequentially formed at the top of the conductive layer 350A.

The first conductive upper semiconductor layer 322A may be formed using, for example, a semiconductor material having a formula of AlₓIn_{y}Ga_{(1-x-y)}N (0≦x≦1, 0≦y≦1, 0≦x+y≦1). The first conductive upper semiconductor layer 322A may be formed of one or more selected from among GaN, InN, AlN, InGaN, AlGaN, InAlGaN, AlInN, AlGaAs, InGaAs, AlInGaAs, GaP, AlGaP, InGaP, AlInGaP, and InP.

The active layer 324 may be formed to have at least one of a single well structure, a multi well structure, a single quantum well structure, a multi quantum well structure, a quantum-wire structure, or a quantum dot structure. For example, trimethyl gallium (TMGa), ammonia (NH₃), nitrogen (N₂), or trimethyl indium (TMIn) may be injected into the active layer 324 such that the active layer 324 has a multi quantum well structure. However, the disclosure is not limited thereto.

A well layer/barrier layer of the active layer 324 may be formed to have one or more pair structures selected from among InGaN/GaN, InGaN/InGaN, GaN/AlGaN, InAlGaN/GaN, GaAs InGaAs)/AlGaAs, and GaP(InGaP)/AlGaP. However, the disclosure is not limited thereto. The well layer may be formed of a material having a narrower band gap than the barrier layer.

A conductive clad layer (not shown) may be further formed on and/or under the active layer 324. The conductive clad layer may be formed of a semiconductor having a wider band gap than the barrier layer of the active layer 324. For example, the conductive clad layer may be formed to have GaN, AlGaN, InAlGaN, or a super lattice structure, etc. In addition, the conductive clad layer may be doped as an fl-type or p-type semiconductor.

The second conductive semiconductor layer 326 may be formed using a group III-V or II-VI compound semiconductor. The second conductive semiconductor layer 326 may be doped with a second conductive dopant. The second conductive semiconductor layer 326 may be formed using, for example, a semiconductor material having a formula of InₓAl_{y}Ga_{1-x-y}N (0≦x≦1, 0≦y≦1, 0≦x+y≦1). In a case in which the second conductive semiconductor layer 326 is a p-type semiconductor layer, the second conductive dopant may include Mg, Zn, Ca, Sr, or Ba, etc., as a p-type dopant.

Subsequently, as shown in FIG. 9d, the first conductive upper semiconductor layer 322A, the active layer 324, and the second conductive semiconductor layer 326 are mesa-etched to expose a portion of the first conductive upper semiconductor layer 322A and a portion of the conductive layer 350A.

Subsequently, as exemplarily shown in FIG. 4, a first electrode 330 is formed at the top of the conductive layer 350A while bypassing the first conductive upper semiconductor layer 322A exposed by mesa etching. At the same time, a second electrode 332 is formed at the top of the second conductive semiconductor layer 326. In addition, the first and second electrodes 330 and 332 may each be formed using a reflective electrode material exhibiting an ohmic property. For example, the first and second electrodes 330 and 332 may each be formed to have a single or multi layer structure including at least one selected from among aluminum (Al), titanium (Ti), chrome (Cr), nickel (Ni), copper (Cu), and gold (Au).

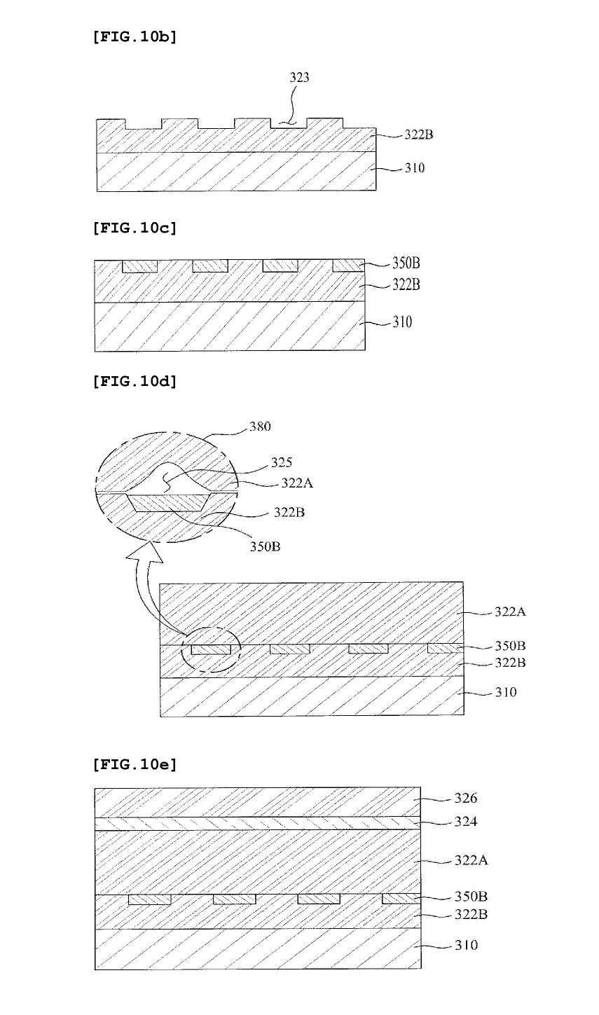

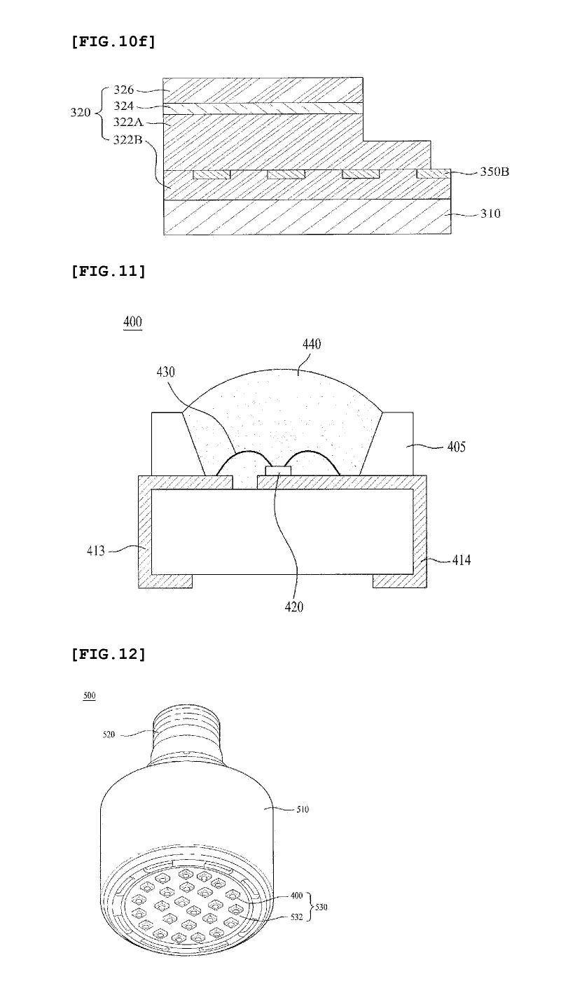

Hereinafter, a method of manufacturing the light emitting device 3003 shown in FIG. 5 according to an embodiment will be described with reference to FIGS. 10a to 10f. However, the disclosure is not limited thereto. The light emitting device 300B shown in FIG. 5 may be manufactured using other different methods.

FIGS. 10a to 10f are sectional views illustrating a method of manufacturing the light emitting device 300B shown in FIG. 5 according to an embodiment.

Referring FIG. 10a, a first conductive lower semiconductor layer 322B is formed on a substrate 310. FIG. 10a is identical to FIG. 9a, and thus a detailed description thereof will be omitted.

Subsequently, as shown in FIG. 10b, a recess 323 is formed at the top of the first conductive lower semiconductor layer 322B. The recess 323 may be formed by an ordinary photolithography process. However, the disclosure is not limited thereto.

Subsequently, as shown in FIG. 10c, the recess 323 formed at the top of the first conductive lower semiconductor layer 322B is filled with a conductive layer 350B. The conductive layer 350B may be formed using a material exhibiting a reflection property as well as electric conductivity. For example, the conductive layer 350A may be formed using a material or an alloy of materials selected from a group consisting of titanium (Ti), platinum (Pt), tantalum (Ta), molybdenum (Mo), silicon (Si), tungsten (W), copper (Cu), aluminum (Al), silver (Ag), and rhodium (Rh), or a material selectively including gold (Au), a copper alloy (Cu alloy), nickel (Ni), copper-tungsten (Cu—W), and a carrier wafer(e.g. GaN, Si, Ge, GaAs, ZnO, SiGe, SiC, SiGe, and Ga₂O₃, etc).

Subsequently, as shown in FIG. 10d, a first conductive upper semiconductor layer 322A is formed at the top of the first conductive lower semiconductor layer 3223 and the conductive layer 3503. The first conductive upper semiconductor layer 322A may be formed using, for example, a semiconductor material having a formula of AlₓIn_{y}Ga_{(1-x-y)}N (0≦x≦1, 0≦y≦1, 0≦x+y≦1). The first conductive upper semiconductor layer 322A may be formed of one or more selected from among GaN, InN, AlN, InGaN, AlGaN, InAlGaN, AlInN, AlGaAs, InGaAs, AlInGaAs, GaP, AlGaP, InGaP, AlInGaP, and InP.

At this time, referring to an enlarged portion 380 of FIG. 10d, when the thickness of the first conductive upper semiconductor layer 322A formed at the top of the first conductive lower semiconductor layer 3223 increases to a crystal thickness or more, the growth mode of the first conductive upper semiconductor layer 322A is changed from a three-dimensional growth mode to a two-dimensional growth mode due to fusion of an island formed by the first conductive upper semiconductor layer 322A. According to such a growth mechanism, an air layer 325 may be formed at the top of the conductive layer 350B. The air layer 325 may contribute to the decrease of dislocation density.

Subsequently, as shown in FIG. 10e, an active layer 324 and a second conductive semiconductor layer 326 are sequentially formed at the top of the first conductive upper semiconductor layer 322A by stacking. Processes shown in FIGS. 10e and 10f are identical to those shown in FIGS. 9c and 9d, respectively, and thus a detailed description thereof will be omitted.

Hereinafter, configuration and operation of a light emitting device package including a light emitting device will be described.

FIG. 11 is a sectional view showing a light emitting device package 400 according to an embodiment.

The light emitting device package 400 includes a package body 405, first and second lead frames 413 and 414 installed at the package body 405, a light emitting device 420 disposed at the package body 405 such that the light emitting device 420 is electrically connected to the first and second lead frames 413 and 414, and a molding member 440 surrounding the light emitting device 420.

The package body 405 may include silicon, synthetic resin, or metal. The package body 405 may have an inclined plane formed around the light emitting device 420.

The first and second lead frames 413 and 414 are electrically isolated from each other. The first and second lead frames 413 and 414 provide power to the light emitting device 420. In addition, the first and second lead frames 413 and 414 may reflect light emitted from the light emitting device 420 to increase light efficiency or discharge heat generated from the light emitting device 420 outward.

The light emitting device 420 may be the light emitting device 100, 200, 300A, or 300B shown in each of FIGS. 2 to 5. However, the disclosure is not limited thereto.

As exemplarily shown in FIG. 11, the light emitting device 420 may be disposed on the first or second lead frame 413 or 414. However, the disclosure is not limited thereto. The light emitting device 420 may be disposed on the package body 405.

The light emitting device 420 may be electrically connected to the first and/or second lead frame 413 or 414 using at least one Of wire bonding, flip chip bonding, or die bonding. The light emitting device 420 shown in FIG. 11 is electrically connected to the first and second lead frames 413 and 414 via wires 430. However, the disclosure is not limited thereto.

The molding member 440 may surround the light emitting device 420 to protect the light emitting device 420. In addition, the molding member 440 may include a fluorescent substance to change the wavelength of light emitted from the light emitting device 420.

A plurality of light emitting device packages according to an embodiment is arrayed on a board. Optical members, such as a light guide plate, a prism sheet, diffusion sheet, and a fluorescent sheet, may be disposed on a path of light emitted from the light emitting device packages. The light emitting device packages, the board, and the optical members may function as a backlight unit or a lighting unit. For example, a lighting system may include a backlight unit, a lighting unit, an indicator, a lamp, and a streetlight.

FIG. 12 is a perspective view showing a lighting unit 500 according to an embodiment. However, the lighting unit 500 of FIG. 12 is an example of the lighting system and thus the disclosure is not limited thereto.

The lighting unit 500 may include a case body 510, connection terminal 520 installed t the case body 510 for receiving power from an external power source, and a light emitting module 530 installed at the case body 510.

The case body 510 may be formed of a material exhibiting an excellent heat dissipation property. For example, the case body 510 may be formed of a metal or a resin.

The light emitting module 530 may include a board 532 and at least one light emitting device package 400 mounted on the board 532.

The board 532 may be an insulator having a circuit pattern printed thereon. For example, the board 532 may include a general printed circuit board (PCB), a metal core PCB, a flexible PCB, a ceramic PCB, etc.

In addition, the board 532 may be formed of a material which efficiently reflects light or the surface of the board 532 may be coated with a color, such as white or silver, which efficiently reflects light.

At least one light emitting device package 400 may be mounted on the board 532. The light emitting device package 400 may include at least one light emitting device 420, e.g. a light emitting diode (LED). The light emitting diode may include a color light emitting diode which emits a color light, such as a red light, a green light, a blue light, or a white light and an ultraviolet (UV) light emitting diode which emits UV light.

The light emitting module 530 may be disposed to have various combinations of light emitting device packages 400 so as to obtain color tone and luminance. For example, a white light emitting diode, a red light emitting diode, and a green light emitting diode may be combined to obtain a high color rendering index (CRI).

The connection terminal 520 may be electrically connected to the light emitting module 530 for supplying power to the light emitting module 530. In this embodiment, the connection terminal 520 is of a socket type, in which the connection terminal 520 is threadedly engaged into the external power source. However, the disclosure is not limited thereto. For example, the connection terminal 520 may be of a pin type, in which the connection terminal 520 may be inserted into the external power source, or may be connected to the external power source via a wire.

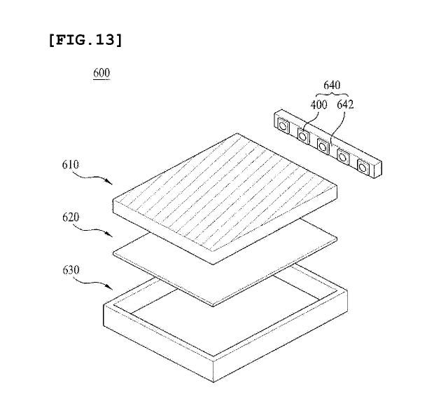

FIG. 13 is an exploded perspective view showing a backlight unit 600 according to an embodiment. However, the backlight unit 600 of FIG. 13 is an example of the lighting system and thus the disclosure is not limited thereto.

The backlight unit 600 includes a light guide plate 610, a reflective member 620 disposed under the light guide plate 610, a bottom cover 630, and a light emitting module 640 for providing light to the light guide plate 610. The light guide plate 610, the reflective member 620, and the light emitting module 640 are received in the bottom cover 630.

The light guide plate 610 diffuses light to provide a surface light source. The light guide plate 610 is formed of a transparent material. For example, the light guide plate 610 may be formed of any one selected from among polymethyl methacrylate (PMMA), polyethylene terephthalate (PET), poly carbonate (PC), cycloolefin copolymer (COC), and polyethylene naphthalate (PEN).

The light emitting module 640 provides light to at least one side of the light guide plate 610. In the end, the light emitting module 640 serves as a light source of a display device in which the backlight unit is installed.

The light emitting module 640 may abut on the light guide plate 610. However, the disclosure is not limited thereto. Specifically, the light emitting module 640 includes a board 642 and a plurality of light emitting device packages 400 mounted on the board 642. The board 642 may abut on the light guide plate 610. However, the disclosure is not limited thereto.

The board 642 may be a PCB including a circuit pattern (not shown). The board 642 may include a metal core PCB and a flexible PCB as well as a general PCB. However, the disclosure is not limited thereto.

The light emitting device packages 400 may be mounted on the board 642 such that a light emission surface of each light emitting device package, from which light is emitted, is spaced apart from the light guide plate 610 by predetermined distance.

The reflective member 620 may be disposed under the light guide plate 610. The reflective member 620 reflects light incident Upon the bottom of the light guide plate 610 upward to improve luminance of the backlight unit. The reflective member 620 may be formed of, for example, PET, PC, or PVC. However, the disclosure is not limited thereto.

The bottom cover 630 may receive the light guide plate 610, the light emitting module 640, and the reflective member 620. To this end, the bottom cover 630 may be formed in the shape of a box open at the top thereof. However, the disclosure is not limited thereto.

The bottom cover 630 may be formed of a metal or a resin. The bottom cover 630 may be manufactured by press molding or extrusion molding.

Although embodiments have been described with reference to a number of illustrative embodiments thereof, it should be understood that numerous other modifications and applications may be devised by those skilled in the art that will fall within the intrinsic aspects of the embodiments. More particularly, various variations and modifications are possible in concrete constituent elements of the embodiments. In addition, it is to be understood that differences relevant to the variations and modifications fall within the spirit and scope of the present disclosure defined in the appended claims.

### MODE FOR INVENTION

Various embodiments have been described in the best mode for carrying out the invention.

### INDUSTRIAL APPLICABILITY

In a light emitting device according to embodiments, a conductive layer disposed between a light emitting layer and a substrate is electrically connected to a first electrode. As a result, the flow of carriers from the first electrode to an active layer is uniform. Consequently, it is possible to reduce driving voltage, to improve internal quantum efficiency, and to fundamentally prevent local heating of the light emitting device, thereby improving reliability of the light emitting device. In addition, the conductive layer is disposed in the middle of a first conductive semiconductor, i.e. between a first conductive lower semiconductor layer and a first conductive upper semiconductor layer. Consequently, it is possible to improve dislocation density.

1. A light emitting device comprising:
a silicon substrate;
a light emitting structure disposed on the silicon substrate, the light emitting structure comprising a first conductive semiconductor layer, an active layer, and a second conductive semiconductor layer;
a conductive layer disposed between the silicon substrate and the first conductive semiconductor layer, the conductive layer being opposite to the active layer;
a first electrode disposed on the first conductive semiconductor layer, the first electrode being electrically connected to the conductive layer while penetrating the first conductive semiconductor layer or while bypassing the first conductive semiconductor layer; and
a second electrode disposed on to the second conductive semiconductor layer.

2. The light emitting device according to claim 1, wherein the silicon substrate has a (ill) crystal plane as a principal plane.

3. The light emitting device according to claim 1, wherein the conductive layer comprises a material exhibiting a reflection property.

4. The light emitting device according to claim 1, wherein the conductive layer comprises;
a first area opposite to the active layer; and
a second area extending from the first area, the second area being connected to the first electrode.

5. The light emitting device according to claim 1, wherein the conductive layer and the first electrode are formed of the same material.

6. The light emitting device according to claim 1, wherein a penetration part of the first electrode penetrating the first conductive semiconductor layer has a width of 0.5 μm to 1.5 μm.

7. The light emitting device according to claim 1, wherein the first electrode comprises:
a first segment disposed on the first conductive upper semiconductor layer in a first direction; and
a second segment extending from the first segment in a second direction different from the first direction, the second segment electrically contacting the conductive layer.

8. The light emitting device according to claim 1, further comprising another first conductive semiconductor layer, different from the first conductive semiconductor layer, disposed between the conductive layer and the silicon substrate.

9. The light emitting device according to claim 1, wherein the conductive layer is formed in a plate shape, separated line shape, or a grid shape.

10. The light emitting device according to claim 1, wherein the conductive layer has a light extraction pattern for reflecting light from the active layer.

11. The light emitting device according to claim 10, wherein the light extraction pattern is formed in a periodic or non-periodic shape.

12. The light emitting device according to claim 10, wherein the light extraction pattern has a convex-concave structure.

13. The light emitting device according to claim 10, wherein the light extraction pattern is formed in a hemispherical shape, truncated shape, or a secondary prism shape.

14. The light emitting device according to claim 10, wherein the light extraction pattern is formed in an irregular saw-toothed shape or a rectangular shape.

15. The light emitting device according to claim 1, wherein the conductive layer has a thickness of 100 nm to 500 nm.

16. The light emitting device according to claim 1, wherein the conductive layer is formed of a material or an alloy of materials selected from a group consisting of titanium (Ti), nickel (Ni), gold (Au), platinum (Pt), tantalum (Ta), molybdenum (Mo), silicon (Si), tungsten (W), copper (Cu), aluminum (Al), silver (Ag), and rhodium (Rh).

17. The light emitting device according to claim 1, wherein the conductive layer selectively comprises gold (Au), a copper alloy (Cu alloy), nickel (Ni), copper-tungsten (Cu—W), or a carrier wafer.

18. The light emitting device according to claim 1, wherein the conductive layer is a single body.

19. The light emitting device according to claim 1, wherein the conductive layer is divided into a plurality of sub bodies spaced apart from each other.

20. The light emitting device according to claim 19, further comprising an air layer disposed between the sub bodies of the conductive layer and the first conductive semiconductor layer.
